(19) United States
(12) Patent Application Publication
(10) Pub. No.: US 2016/0204136 A1
(43) Pub. Date: Jul. 14, 2016

(54) TRANSISTOR AND LIQUID CRYSTAL DISPLAY DEVICE HAVING THE SAME

(71) Applicant: SAMSUNG DISPLAY CO., LTD, Yongin-City (KR)

(72) Inventors: Noboru TAKEUCHI, Yongin-City (KR); Min-Soo KANG, Yongin-City (KR); Beom-Jun Kim, Yongin-City (KR); Yoon-Ho Kim, Yongin-City (KR); Seong-Yeol SYN, Yongin-City (KR); Hong-Woo Lee, Yongin-City (KR)

(21) Appl. No.: 14/968,634

(22) Filed: Dec. 14, 2015

(30) Foreign Application Priority Data
Jan. 9, 2015 (KR) 10-2015-0003522

(51) Int. Cl. H01L 27/12; H01L 29/786; H01L 23/31; H01L 29/49; G09G 3/36; G02F 1/1333; G02F 1/1362; G02F 1/1343; G06F 1/04; H01L 29/24; G02F 1/1368

(52) U.S. Cl. CPC H01L 27/1225; H01L 29/24; H01L 29/7869; H01L 23/3171; H01L 29/78648; H01L 29/4908; H01L 29/495; H01L 29/4966; H01L 27/1251; G02F 1/1368; G02F 1/133345; G02F 1/136227; G02F 1/134309; G02F 1/13439; G06F 1/04; G09G 3/3677; G09G 3/3648; G09G 2300/0809; G09G 2300/0426

(57) ABSTRACT

A transistor and a liquid crystal display device having the same are provided. The transistor includes a first gate electrode disposed on a base substrate; a gate insulating layer disposed on the first gate electrode; a semiconductor layer disposed on the gate insulating layer, and including a channel area; a source electrode and a drain electrode connected to both ends of the semiconductor layer; a passivation layer configured to cover the semiconductor layer, the source electrode, and the drain electrode; and a second gate electrode disposed on the passivation layer, and partially overlapping the channel area in a direction from the drain electrode toward the source electrode.

### CLAIM OF PRIORITY

This application claims the priority to and all the benefits accruing under 35 U.S.C. 119 of Korean Patent Application No. 10-2015-0003522, filed on Jan. 9, 2015, in the Korean Intellectual Property Office (KIPO), the entire contents of which are incorporated herein by reference in their entirety.

### BACKGROUND OF THE INVENTION

1. Field of Disclosure

The present invention relates to a transistor and a liquid crystal display device having the same.

2. Description of the Related Art

A liquid crystal display device generates an electric field between two substrates, and motivates liquid crystal molecules of a liquid crystal layer by the electric field. Transmittance of light which passes through the liquid crystal layer is adjusted by the movement of the liquid crystal molecules, and thus, the liquid crystal display device provides an image to a viewer.

The liquid crystal display device includes a display panel and a panel driving part. The display panel includes a plurality of gate lines and a plurality of data lines. The panel driving part includes a gate driving part which provides gate signals to the plurality of gate lines and a data driving part which provides data voltages to the data lines.

The gate driving part is disposed on a side of the display panel. Also, the gate driving part includes a plurality of switching devices, and the switching devices may be thin film transistors. When a high voltage is applied between a source electrode and a drain electrode of the switching device, some of the thin film transistors of the gate driving part may be degraded. Characteristics of the thin film transistors are changed by the degradation, and thus, reliability of the gate driving part may be decreased and a lifetime may be decreased.

### SUMMARY OF THE INVENTION

The present invention is directed to a transistor capable of preventing degradation to increase reliability.

The present invention is also directed to a liquid crystal display device including the transistor.

One aspect of the present invention provides a transistor including a first gate electrode disposed on a base substrate; a gate insulating layer disposed on the first gate electrode; a semiconductor layer disposed on the gate insulating layer, and including a channel area; a source electrode and a drain electrode connected to both ends of the semiconductor layer; a passivation layer configured to cover the semiconductor layer, the source electrode, and the drain electrode; and a second gate electrode disposed on the passivation layer, and partially overlapping the channel area in a direction from the drain electrode toward the source electrode.

An overlap ratio between the gate electrode and the channel area may be equal to or more than 20% and less than 100% of a length of the channel area, and preferably, the overlap ratio between the gate electrode and the channel area may be equal to or more than 20% and less than 60% of the length of the channel area.

The second gate electrode may be disposed on the passivation layer, and contact the drain electrode through a contact hole exposing the drain electrode.

The second gate electrode may include one of a transparent conductive oxide and a low resistive metal, and the low resistive metal may include one of MoTi, Cu, MoNb, Mo, Cr, and AlNd.

Another aspect of the present invention provides a liquid crystal display device including a liquid crystal display panel including a first substrate divided into a display portion and a peripheral portion, a second substrate facing the first substrate in the display portion, and a liquid crystal layer interposed between the first substrate and the second substrate; and a gate driving part disposed on the first substrate in the peripheral portion. Here, the gate driving part includes a pull-up control part configured to apply any one carry signal among previous stages to a first node in response to the one carry signal among the previous stages; a pull-up part configured to output a clock signal as an Nth gate output signal in response to a signal applied to the first node; a carry part configured to output the clock signal as an Nth carry signal in response to the signal applied to the first node; a first pull-down part including a plurality of transistors connected in series, and configured to pull-down the first node to a second off signal in response to any one carry signal among next stages; and a second pull-down part configured to pull-down the Nth gate output signal as a first off signal response to the one carry signal among the next stages. The pull-up control part includes a transistor, and the transistor includes a first gate electrode and a first source electrode connected to a terminal which applies the one carry signal among the previous stages, and a first drain electrode and a second gate electrode connected to the first node.

The first and second gate electrodes may be first and second control electrodes, and the first source electrode may be an input electrode, and the first drain electrode may be an output electrode.

In the display portion, the first substrate may include a thin film transistor formed on a base substrate; a first passivation layer disposed on the thin film transistor; a common electrode disposed on the first passivation layer; a second passivation layer disposed on the common electrode; and a pixel electrode disposed on the second passivation layer.

The thin film transistor may include a third gate electrode formed on the base substrate; a gate insulating layer configured to cover the third gate electrode; a first semiconductor layer disposed on the gate insulating layer; and a second source electrode and a second drain electrode connected to both end portions of the first semiconductor layer. Here, the gate insulating layer, the first passivation layer, and the second passivation layer may extend toward the peripheral portion.

The transistor may include the first gate electrode disposed on the base substrate; a second semiconductor layer disposed on the gate insulating layer, and including a channel area; the first source electrode and the first drain electrode connected to both ends of the first semiconductor layer; and a second gate electrode disposed on the first passivation layer, and configured to overlap a portion of the channel area in a direction from the first drain electrode toward the first source electrode.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings, in which like reference symbols indicate the same or similar components, wherein:

FIG. 1 is a block diagram illustrating a display device according to an embodiment of the present invention;

FIG. 2 is an equivalent circuit diagram illustrating an N^{th} stage of a gate driving part of FIG. 1;

FIG. 3 is a cross-sectional view illustrating a display portion of a display panel of FIG. 1;

FIG. 4 is a cross-sectional view illustrating a fourth transistor shown in FIG. 2; and

FIGS. 5 and 6 are views illustrating an electric field in a channel area adjacent to a drain electrode based on presence of a third gate electrode of a fourth transistor.

### DETAILED DESCRIPTION OF THE INVENTION

It is important to understand that the present invention may be embodied in many alternative forms and should not be construed as limited to the example embodiments set forth herein. While the invention is susceptible to various modifications and alternative forms, specific embodiments thereof are shown by way of example in the drawings and will herein be described in detail. It should be understood, however, that there is no intent to limit the invention to the particular forms disclosed, but on the contrary, the invention is to cover all modifications, equivalents, and alternatives falling within the spirit and scope of the invention.

In describing each drawing, like numerals are used for like elements. In the enclosed drawings, the sizes and relative sizes of layers and regions may be exaggerated for clarity. Like numerals refer to like elements throughout. It will be understood that, although the terms first, second, etc. may be used herein to describe various elements, these elements should not be limited by these terms. These terms are used to distinguish one element from another. For example, a first element discussed below could be termed a second element without departing from the teachings of the present inventive concept. Also, a second element discussed below could be termed a first element without departing from the teachings of the present inventive concept. As used herein, the singular forms are intended to include the plural forms as well, unless the context clearly indicates otherwise.

It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. It will be further understood that the terms “disposed on” when used in this specification, specify the presence of stated layers, films, areas, plates, and/or the like, but also include “disposed directly on” and intervening another part therebetween. On the contrary, it will be further understood that the terms “disposed under”, also include “disposed directly under” and intervening another part therebetween.

Hereinafter, exemplary embodiments of the present invention will be described in detail with reference to the accompanying drawings.

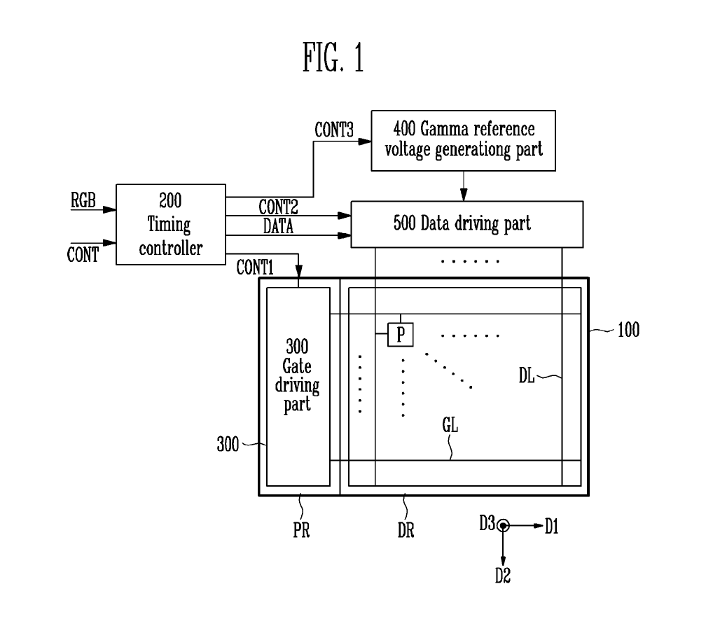

FIG. 1 is a block diagram illustrating a display device according to an embodiment of the present invention.

Referring to FIG. 1, the display device includes a liquid crystal display panel 100 and a panel driving part. The panel driving part includes a timing controller 200, a gate driving part 300, a gamma reference voltage generating part 400, and a data driving part 500.

The liquid crystal display panel 100 includes a display portion which displays an image and a peripheral portion disposed adjacent to the display portion.

The liquid crystal display panel 100 includes a plurality of gate lines GL, a plurality of data lines DL, and a plurality of unit pixels P each electrically connected to the gate lines GL and the data lines DL. The gate lines GL extend in a first direction D1, and the data lines DL extend in a second direction D2 which crosses the first direction D1.

Each unit pixel P may include a switching device (not shown), a liquid crystal capacitor (not shown) electrically connected to the switching device, and a storage capacitor (not shown). The unit pixels P may be arranged in a matrix shape.

The timing controller 200 receives input image data RGB and an input control signal CONT from a device (not shown) of the outside. The input image data may include red image data R, green image data G, and blue image data B. The input control signal CONT includes a driving mode signal which includes a 2-dimensional mode and a 3-dimensional mode. The input control signal CONT may further include a master clock signal and a data enable signal. The input control signal CONT may further include a vertical synchronizing signal and a horizontal synchronizing signal.

The timing controller 200 generates a first control signal CONT1, a second control signal CONT2, a third control signal CONT3, and a data signal DATA based on the input image data RGB and the input control signal CONT.

The timing controller 200 generates the first control signal CONT1 configured to control an operation of the gate driving part 300 based on the input control signal CONT, thereby outputting the generated first control signal CONT1 to the gate driving part 300. The first control signal CONT1 may include the driving mode signal. The first control signal CONT1 may include a vertical start signal and a gate clock signal.

The timing controller 200 generates the second control signal CONT2 configured to control an operation of the data driving part 500 based on the input control signal CONT, thereby outputting the generated second control signal CONT2 to the data driving part 500. The second control signal CONT2 may include the driving mode signal. The second control signal CONT2 may include a horizontal start signal and a load signal.

The timing controller 200 generates the data signal DATA based on the input image data RGB. The timing controller 200 outputs the data signal DATA to the data driving part 500.

The timing controller 200 generates the third control signal CONT3 configured to control the gamma reference voltage generating part 400 based on the input control signal CONT, thereby outputting the generated third control signal CONT3 to the gamma reference voltage generating part 400.

The gate driving part 300 generates gate signals configured to drive the gate lines GL in response to the first control signal CONT1 input from the timing controller 200. The gate driving part 300 sequentially outputs the gate signals to the gate lines GL.

The gate driving part 300 may be integrated on the peripheral portion of the liquid crystal display panel 100.

The gamma reference voltage generating part 400 generates a gamma reference voltage VGREF in response to the third control signal CONT3 input from the timing controller 200. The gamma reference voltage generating part 400 provides the gamma reference voltage VGREF to the data driving part 500. The gamma reference voltage VGREF has values each corresponding to the data signal DATA.

The gamma reference voltage generating part 400 may be disposed in the timing controller 200 or in the data driving part 500.

The data driving part 500 receives the second control signal CONT2 and the data signal DATA from the timing controller 200, and receives the gamma reference voltage VGREF from the gamma reference voltage generating part 400. The data driving part 500 transforms the data signal DATA into data voltages in an analog type using the gamma reference voltage VGREF. The data driving part 500 outputs the data voltages to the data lines DL.

The data driving part 500 may include a shift register (not shown), a latch (not shown), a signal processing part (not shown), and a buffer part (not shown). The shift register may output a latch pulse to the latch. The latch temporarily stores the data signal DATA, and then, outputs the stored data signal DATA to the signal processing part. The signal processing part generates the data voltages in the analog type based on the data signal DATA of the digital type and the gamma reference voltage VGREF and outputs the generated data voltages to the buffer part. The buffer part compensates the data voltages to have a constant level, and thus, outputs the data voltages to the data lines DL.

The data driving part 500 may be directly mounted on the liquid crystal display panel 100, or connected to the liquid crystal display panel 100 as a tape carrier package (TCP) shape. Meanwhile, the data driving part 500 may be integrated into the peripheral portion of the liquid crystal display panel 100.

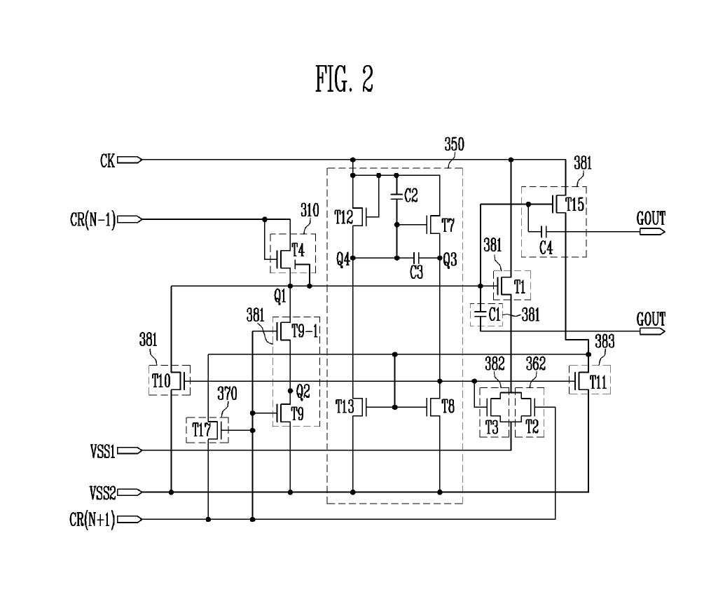

FIG. 2 is an equivalent circuit diagram illustrating an N^{th} stage of a gate driving part of FIG. 1.

Referring to FIGS. 1 and 2, the gate driving part 300 receives a first clock signal CK, a second clock signal CKB, a first off voltage VSS1, and a second off voltage VSS2. The gate driving part 300 outputs a gate output signal GOUT.

The first clock signal CK is applied to a first clock terminal, and the second clock signal CKB is applied to a second clock terminal, and the first off voltage VSS1 is applied to a first off terminal, and the second off voltage VSS2 is applied to a second off terminal, and the gate output signal GOUT is applied to a gate output terminal.

The first clock signal CK is a square wave signal alternating between a high level and a low level. The high level of the first clock signal CK may have a gate on voltage. The low level of the first clock signal CK may have the second off voltage VSS2. A duty ratio of the first clock signal CK may be 50%. In another embodiment of the present invention, the duty ratio of the first clock signal CK may be smaller than 50%. The first clock signal CK may be applied to odd numbered stages or even numbered stages of the gate driving part 300. For example, the gate on voltage may be about 15 V to about 20 V.

The second clock signal CKB is a square wave signal alternating between a high level and a low level. The high level of the second clock signal CKB may have a gate on voltage. The low level of the second clock signal CKB may have the second off voltage VSS2. A duty ratio of the second clock signal CKB may be 50%. In another embodiment of the present invention, the duty ratio of the second clock signal CKB may be smaller than 50%. The second clock signal CKB may be applied to odd numbered stages or even numbered stages of the gate driving part 300. For example, when the first clock signal CK is applied to odd numbered stages of the gate driving part 300, the second clock signal CKB is applied to even numbered stages of the gate driving part 300. For example, when the first clock signal CK is applied to even numbered stages of the gate driving part 300, the second clock signal CKB is applied to odd numbered stages of the gate driving part 300. For example, the second clock signal CKB may be an inverted signal of the first clock signal CK.

The first off voltage VSS1 may be a direct current voltage. The second off voltage VSS2 may be a direct current voltage. The second off voltage VSS2 may have a level smaller than that of the first off voltage VSS1. For example, the first off voltage VSS1 may be about −5 V. For example, the second off voltage VSS2 may be about −10 V.

The N^{th} stage is operated in response to an N−1^{th} carry signal CR(N−1) of an N−1^{th} stage, which is a prior stage to the N^{th} stage, and thus, outputs an N^{th} gate output signal GOUT and an N^{th} carry signal CR(N). The N^{th} stage is operated in response to an N+1^{th} carry signal CR(N+1) of an N+1^{th} stage, which is a next stage to the N^{th} stage, and thus, pulls down the N^{th} gate output signal GOUT to the first off voltage VSS1. N is a natural number.

According to the above described method, first to last stages sequentially each output the gate output signals GOUT.

The N−1^{th} carry signal CR(N−1) is applied to an N−1^{th} carry terminal, and the N+1^{th} carry signal CR(N+1) is applied to an N+1^{th} carry terminal, and the N^{th} carry signal CR(N) is output to an N^{th} carry terminal.

The N^{th} stage includes a pull-up control part 310, a storage part 320, a pull-up part 330, a carry part 340, an inverting part 350, a first pull-down part 361, a second pull-down part 362, a carry stabilizing part 370, a first holding part 381, a second holding part 382, and a third holding part 383.

The pull-up control part 310 includes a fourth transistor T4, and the fourth transistor T4 includes a first control electrode and an input electrode which are connected to the N−1^{th} carry terminal, and an output electrode and a second control electrode which are connected to a first node Q1. The first node Q1 is connected to a control electrode of the pull-up part 330. Here, the fourth transistor T4 may be a pull-up control transistor. Also, the control electrodes may be gate electrodes, and the input electrode and the output electrode may be a source electrode and a drain electrode. Meanwhile, the second control electrode may prevent concentration of an electric field on a channel adjacent to the output electrode to which a high voltage is applied. Thus, the second control electrode may prevent degradation of a channel interposed between the input electrode and the output electrode. Therefore, reliability of the gate driving part 300 may be improved.

Meanwhile, in the embodiment of the present invention, a structure, in which the second control electrode of the fourth transistor T4 is connected to the first node Q1, is described, but the present invention is not limited to the above structure. The second control electrode may be connected to a wire or a terminal configured to output substantially the same voltage as a voltage output from the output electrode of the fourth transistor T4.

The storage part 320 includes a storage capacitor C1, and the storage capacitor C1 includes a first electrode connected to the first node Q1 and a second electrode connected to the gate output terminal.

The pull-up part 330 includes a first transistor T1, and the first transistor T1 includes a control electrode connected to the first node Q1, an input electrode connected to the first clock terminal, and an output electrode connected to the gate output terminal.

The carry part 340 includes a the fifteenth transistor T15 and a fourth capacitor C4, and the fifteenth transistor T15 includes a control electrode connected to the first node Q1, an input electrode connected to the first clock terminal, and an output electrode connected to the N^{th} carry terminal. The fourth capacitor C4 includes a first electrode connected to the first node Q1 and a second electrode connected to the N^{th} carry terminal.

The inverting part 350 includes a twelfth transistor T12, a seventh transistor T7, a thirteenth transistor T13, an eighth transistor T8, a second capacitor C2, and a third capacitor C3. The twelfth transistor T12 includes a control electrode and an input electrode which are connected to the first clock terminal, and an output electrode connected to a fourth node Q4. The seventh transistor T7 includes a control electrode connected to the fourth node Q4, an input electrode connected to the first clock terminal, and an output electrode connected to a third node Q3. The thirteenth transistor T13 includes a control electrode connected to the N^{th} carry terminal, an input electrode connected to the second off terminal, and an output electrode connected to the fourth node Q4. The eighth transistor T8 includes a control electrode connected to the N^{th} carry terminal, an input electrode connected to the second off terminal, and an output electrode connected to the third node Q3. The second capacitor C2 includes a first electrode connected to the first clock terminal and a second electrode connected to the fourth node Q4. The third capacitor C3 includes a first electrode connected to the third node Q3 and a second electrode connected to the fourth node Q4.

Here, the twelfth transistor T12 is a first inverting transistor, and the seventh transistor T7 is a second inverting transistor, and the thirteenth transistor T13 is a third inverting transistor, and the eighth transistor T8 is a fourth inverting transistor.

The first pull-down part 361 includes a plurality of switching device connected in series. For example, the first pull-down part 361 may include two transistors connected in series.

For example, the first pull-down part 361 includes a ninth transistor T9 and a 9−1^{th} transistor T9−1. The ninth transistor T9 includes a control electrode connected to the N+1^{th} carry terminal, an input electrode connected to the second off terminal, and an output electrode connected to a second node Q2. The 9−1^{th} transistor T9−1 includes a control electrode connected to the N+1^{th} carry terminal, an input electrode connected to the second node Q2, and an output electrode connected to the first node Q1.

When the first pull-down part 361 includes one transistor, characteristics of the transistor of the first pull-down part 361 is changed by a voltage between the first node Q1 and the N+1^{th} carry terminal, and thus, reliability of the gate driving part 300 may be decreased.

Since the first pull-down part 361 includes a plurality of transistors connected in series, the voltage applied between the first node Q1 and the N+1^{th} carry terminal may be distributed into the ninth transistor T9 and the 9−1^{th} transistor T9−1. Thus, reliability of the gate driving part 300 may be improved, and lifetime may be increased.

Since the first pull-down part 361 includes a plurality of transistors connected in series, a timing at which the second off voltage VSS2 is transmitted to the first node Q1 is delayed, and thus, the gate output signal GOUT is polled by the first clock signal CK. Thus, a size of a second transistor T2 of the second pull-down part 362 is decreased.

Here, the ninth transistor T9 is a first pull-down transistor, and the 9−1^{th} transistor T9−1 is a second pull-down transistor.

The second pull-down part 362 includes the second transistor T2, and the second transistor T2 includes a control electrode connected to the N+1^{th} carry terminal, an input electrode connected to the first off terminal, and an output electrode connected to the gate output terminal.

The carry stabilizing part 370 includes a seventeenth transistor T17, and the seventeenth transistor T17 includes a control electrode and an input electrode commonly connected to the N+1^{th} carry terminal, and an output electrode connected to the N^{th} carry terminal.

The carry stabilizing part 370 securely removes a noise portion generated by a leakage current which is transmitted through the fourth transistor T4 of the N+1^{th} stage.

The first holding part 381 includes a tenth transistor T10, and the tenth transistor T10 includes a control electrode connected to the third node Q3, an input electrode connected to the second off terminal, and an output electrode connected to the first node Q1.

The second holding part 382 includes a third transistor T3, and the third transistor T3 includes a control electrode connected to the third node Q3, an input electrode connected to the first off terminal, and an output electrode connected to the gate output terminal.

The third holding part 383 includes an eleventh transistor T11, and the eleventh transistor T11 includes a control electrode connected to the third node Q3, an input electrode connected to the second off terminal, and an output electrode connected to the N^{th} carry terminal.

In the embodiment of the present invention, a previous carry signal is not limited to the N−1^{th} carry signal, and may be any one carry signal among previous stages. Also, the next carry signal is not limited to the N+1^{th} carry signal, and may be any one carry signal among next stages. Also, in the embodiment of the present invention, the transistors may be oxide semiconductor transistors.

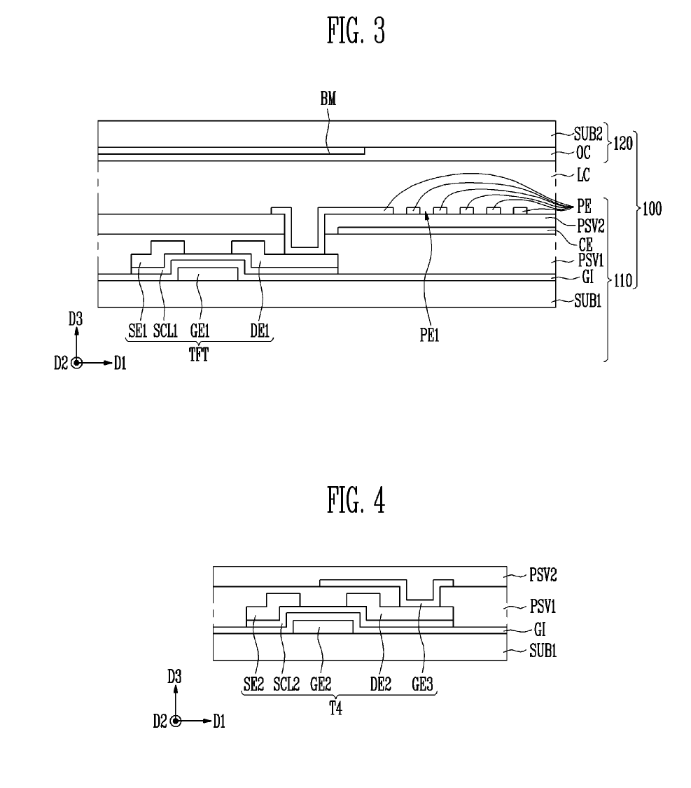

FIG. 3 is a cross-sectional view illustrating a display portion of a display panel of FIG. 1, and FIG. 4 is a cross-sectional view illustrating a fourth transistor shown in FIG. 2.

Referring to FIGS. 1 to 4, the liquid crystal display panel 100 may be divided into a display portion DR configured to display an image and a peripheral portion PR adjacent to the display portion DR, and the gate driving part 300 is disposed in the peripheral portion PR.

Also, in the display portion DR, the liquid crystal display panel 100 may include a first substrate 110, a second substrate 120 facing the first substrate 110, and a liquid crystal layer LC interposed between the first substrate 110 and the second substrate 120.

The first substrate 110 may be a thin film transistor array substrate on which thin film transistors configured to operate the liquid crystal molecules of the liquid crystal layer LC are formed.

The first substrate 110 may include a first base substrate SUB1 into which the display portion DR and the peripheral portion PR are distinguished, a thin film transistor TFT disposed on the first base substrate SUB1, a pixel electrode PE connected to the thin film transistor TFT, and a common electrode CE which forms an electric field with the pixel electrode PE.

The first substrate 110 may include the first base substrate SUB1 which has the display portion. The first base substrate SUB1 may be a rigid type base substrate or a flexible type base substrate. The rigid type base substrate may be any one among a glass base substrate, a quartz base substrate, a glass ceramic base substrate, and a crystalline glass base substrate. The flexible type base substrate may be one among a film base substrate including a high molecular weight organic material and a plastic base substrate. A material applied to the first base substrate SUB1 may have a resistance (or a thermal resistance) with respect to a high process temperature during a manufacturing process.

Gate lines GL extending in one direction, data lines DL crossing the gate lines GL, and thin film transistors TFT connected to the gate lines GL and the data lines DL may be disposed on the first base substrate SUB1.

The thin film transistor TFT may include a first gate electrode GE1 disposed on the first base substrate SUB1 and connected to the gate lines GL, a first semiconductor layer SCL1 partially overlapping the first gate electrode GE1, and a first source electrode SE1 and a first drain electrode DE1 connected to both ends of the first semiconductor layer SCL1.

A gate insulating layer GI may be interposed between the first gate electrode GE1 and the first semiconductor layer SCL1. That is, the gate insulating layer GI may cover the first gate electrode GE1.

The gate insulating layer GI may include at least one of silicon oxide SiOx and silicon nitride SiNx.

The first semiconductor layer SCL1 may be disposed on the gate insulating layer GI, and include an oxide semiconductor material. The oxide semiconductor material may include at least one of zinc (Zn), indium (In), gallium (Ga), tin (Sn), and a mixture thereof. For example, the first semiconductor layer SCL1 may include indium-gallium-zinc oxide (IGZO). Also, in the first semiconductor layer SCL1, an area between areas connected to the first source electrode SE1 and the first drain electrode DE1 may be a channel area of the thin film transistor TFT.

One end of the first source electrode SE1 may be connected to the data lines DL, and the other end of the first source electrode SE1 may be connected to one end of the first semiconductor layer SCL1. The first drain electrode DE1 may be connected to the other end of the first semiconductor layer SCL1, and spaced apart from the first source electrode SE1.

A first passivation layer PSV1 may be disposed on the thin film transistor TFT. The first passivation layer PSV1 may include at least one of an inorganic insulating layer and an organic insulating layer. For example, the first passivation layer PSV1 may include an inorganic insulating layer covering the thin film transistor TFT and an organic insulating layer disposed on the inorganic insulating layer.

The inorganic insulating layer may include at least one of silicon oxide (SiOx) and silicon nitride (SiNx).

The organic insulating layer may include a transparent organic insulating material. For example, the organic insulating layer may include at least one of polyacrylates resin, epoxy resin, phenolic resin, polyamides resin, polyimides rein, unsaturated polyesters resin, poly-phenylenethers resin, poly-phenylenesulfides resin, and benzocyclobutene. Also, the organic insulating layer may add a color to the organic insulating material, and perform as a color filter. The first passivation layer PSV1 may have one color among red, green, blue, cyan, magenta, and yellow.

The common electrode CE may be disposed on the first passivation layer PSV1. The common electrode CE may include a transparent conductive oxide. For example, the common electrode CE may include any one of indium tin oxide (ITO) and indium zinc oxide (IZO).

A second passivation layer PSV2 which covers the common electrode CE may be disposed on the common electrode CE. The second passivation layer PSV2 may include an inorganic insulating material or an organic insulating material. For example, the second passivation layer PSV2 may include silicon oxide (SiOx).

Also, the second passivation layer PSV2 may has a first contact hole exposing a portion of the first drain electrode DE1.

The pixel electrode PE may be disposed on the second passivation layer PSV2, and contact the first drain electrode DE1 through the first contact hole. The pixel electrode PE may include the same material as the common electrode CE. That is, the pixel electrode PE may include any one of indium tin oxide (ITO) and indium zinc oxide (IZO).

Meanwhile, the pixel electrode PE may be patterned to have a plurality of incised portions PE1. Thus, the pixel electrode PE may include a branch portion having a plurality of stripe shapes. The branch portion may form an electric field with the common electrode CE.

The second substrate 120 may include a second base substrate SUB2, a black matrix BM, and a overcoat layer OC.

The black matrix BM may be disposed on a surface of the second base substrate SUB2 which faces the first substrate 110. The black matrix BM may be provided in an area corresponding to an area in which the data line DL is formed, and prevent light leakage caused by misalignment of the liquid crystal molecules.

The overcoat layer OC may cover the black matrix BM. Also, the overcoat layer OC may decrease a step height of the second substrate 120 which is caused by the black matrix BM.

The liquid crystal layer LC may include a plurality of the liquid crystal molecules. The liquid crystal molecules may be arranged in a predetermined direction by an electric field formed between the pixel electrode PE and the common electrode CE. When the liquid crystal molecules are arranged in the predetermined direction, the liquid crystal layer LC adjusts transmittance of light provided from a backlight unit (not shown), and thus, the liquid crystal display panel 100 displays an image.

Meanwhile, in the peripheral portion PR, the liquid crystal display panel 100 may include the gate driving part 300 disposed on the first base substrate SUB1. The fourth transistor T4 among the gate driving part 300 may include two gate electrodes disposed on and below a second semiconductor layer SCL2.

The above will be described in detail. The fourth transistor T4 may include a second gate electrode GE2 disposed on the first base substrate SUB1, the second semiconductor layer SCL2 partially overlapping the second gate electrode GE2, a second source electrode SE2 and a second drain electrode DE2 connected to both ends of the second semiconductor layer SCL2, and a third gate electrode GE3 connected to the second drain electrode DE2.

The second gate electrode GE2 may be connected to the N−1^{th} carry terminal of the gate driving part 300. The gate insulating layer GI may be interposed between the second gate electrode GE2 and the second semiconductor layer SCL2.

The second semiconductor layer SCL2 may be disposed on the gate insulating layer GI. Also, the second semiconductor layer SCL2 may include the same material as the first semiconductor layer SCL1. That is, the second semiconductor layer SCL2 may include an oxide semiconductor material.

Also, in the second semiconductor layer SCL2, an area between areas connected to the second source electrode SE2 and the second drain electrode DE2 may be a channel layer of the fourth transistor T4.

One end of the second source electrode SE2 may be connected to the N−1^{th} carry terminal, and the other end of the second source electrode SE2 may be connected to one end of the second semiconductor layer SCL2.

The second drain electrode DE2 may be connected to the other end of the second semiconductor layer SCL2, and spaced apart from the second source electrode SE2. Also, the second drain electrode DE2 may be connected to the first node Q1.

The first passivation layer PSV1 may be disposed on the fourth transistor T4. The first passivation layer PSV1 may have a second contact hole exposing a portion of the second drain electrode DE2.

In the peripheral portion PR, the third gate electrode GE3 which is connected to the second drain electrode DE2 through the second contact hole may be disposed on the first passivation layer PSV1. The third gate electrode GE3 may include the same material as the common electrode CE. That is, the third gate electrode GE3 may include any one of indium tin oxide (ITO) and indium zinc oxide (IZO). Also, the third gate electrode GE3 may be connected to the first node Q1. Thus, a voltage the same as the voltage output from the second drain electrode DE2 may be applied to the third gate electrode GE3.

Also, a portion of the third gate electrode GE3 may overlap the channel area, and thus, prevent rapid variation of an electric potential in a channel area adjacent to the second drain electrode DE2. The rapid change of the electric potential is a concentration of the electric field. Thus, the third gate electrode GE3 may prevent the concentration of the electric field on the channel area adjacent to the second drain electrode DE2. Therefore, the third gate electrode GE3 may prevent degradation of the fourth transistor.

Also, the third gate electrode GE3 may overlap the channel area in a direction from the second drain electrode DE2 toward the second source electrode SE2. Here, an overlap ratio between the third gate electrode GE3 and the channel area may be equal to or more than 20% and less than 100% of a length of the channel area, that is, a distance between the second source electrode SE2 and the second drain electrode DE2. Preferably, the overlap ratio between the third gate electrode GE3 and the channel area may be equal to or more than 20% and less than 60% of the length of the channel area.

When the overlap ratio between the third gate electrode GE3 and the channel area is less than 20%, the effect of preventing the concentration of the electric field by the third gate electrode GE3 is not sufficient, and thus, the electric field may be concentrated on the channel area adjacent to the second drain electrode DE2. Also, when the overlap ratio between the third gate electrode GE3 and the channel layer is 100%, the effect of preventing the concentration of the electric field by the third gate electrode GE3 may disappear.

The second passivation layer PSV2 covering the third gate electrode GE3 may be disposed on the third gate electrode GE3.

Meanwhile, in the embodiment of the present invention, the third gate electrode GE3 includes the same material as the common electrode CE, but is not limited to the above. The third gate electrode GE3 may include one low resistive metal disposed on the first passivation layer PSV1, for example, may include any one of MoTi, Cu, MoNb, Mo, Cr, and AlNd. Also, the third gate electrode GE3 may include the same material as the pixel electrode PE. That is, the third gate electrode GE3 may include a transparent conductive oxide disposed on the second passivation layer PSV2.

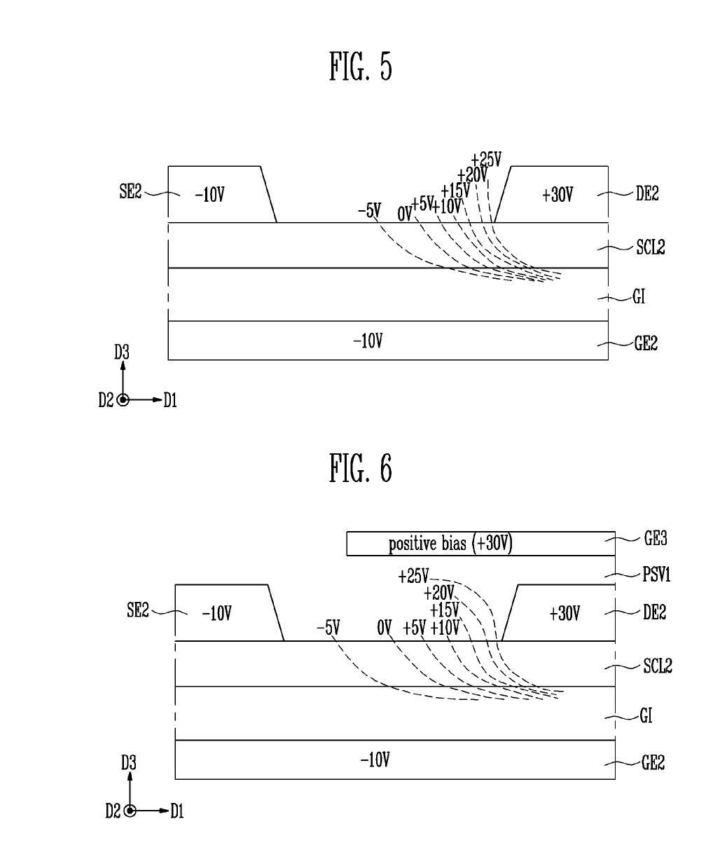

FIGS. 5 and 6 are views illustrating an electric field in a channel area adjacent to a drain electrode based on presence of a third gate electrode of a fourth transistor.

Referring to FIGS. 1 to 6, concentration phenomena of electric fields in channel areas adjacent to drain electrodes are different based on presence of the third gate electrode GE3 of the fourth transistor T4.

As described in FIG. 5, when the fourth transistor T4 includes only the second gate electrode GE2, the electric field may be concentrated on the channel area adjacent to the second drain electrode DE2. This is because the concentration of the electric field is not prevented.

Also, as described in FIG. 6, when the fourth transistor T4 includes the second gate electrode GE2 and the third gate electrode GE3, the electric field is not concentrated on the channel area adjacent to the second drain electrode, but widely distributed. This is because the third gate electrode GE3 prevents the concentration of the electric field. Thus, the third gate electrode GE3 may prevent degradation of the fourth transistor T4.

According to the transistor of the present invention, since electric field is not concentrated on a specific area, degradation may be prevented. Thus, reliability of a gate driving part including the transistor may be improved.

Therefore, a liquid crystal display including the gate driving part provides a stable display quality to a viewer.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A transistor comprising:
a first gate electrode disposed on a base substrate;
a gate insulating layer disposed on the first gate electrode;
a semiconductor layer disposed on the gate insulating layer, and including a channel area;
a source electrode and a drain electrode connected to both ends of the semiconductor layer;
a passivation layer configured to cover the semiconductor layer, the source electrode, and the drain electrode; and
a second gate electrode disposed on the passivation layer, and partially overlapping the channel area in a direction from the drain electrode toward the source electrode.

2. The transistor of claim 1, wherein an overlap ratio between the gate electrode and the channel area is equal to or more than 20% and less than 100% of a length of the channel area.

3. The transistor of claim 2, wherein the overlap ratio between the gate electrode and the channel area is equal to or more than 20% and less than 60% of the length of the channel area.

4. The transistor of claim 2, wherein the second gate electrode is disposed on the passivation layer, and contacts the drain electrode through a contact hole exposing the drain electrode.

5. The transistor of claim 2, wherein the second gate electrode comprises one of a transparent conductive oxide and a low resistive metal.

6. The transistor of claim 5, wherein the low resistive metal comprises one of MoTi, Cu, MoNb, Mo, Cr, and AlNd.

7. The transistor of claim 2, wherein the semiconductor layer comprises an oxide semiconductor material.

8. A liquid crystal display device comprising:
a liquid crystal display panel including a first substrate divided into a display portion and a peripheral portion, a second substrate facing the first substrate in the display portion, and a liquid crystal layer interposed between the first substrate and the second substrate; and
a gate driving part disposed on the first substrate in the peripheral portion,
wherein the gate driving part comprises:
a pull-up control part configured to apply any one carry signal among previous stages to a first node in response to the one carry signal among the previous stages;
a pull-up part configured to output a clock signal as an N^{th} gate output signal in response to the signal applied to the first node;
a carry part configured to output the clock signal as an N^{th} carry signal in response to the signal applied to the first node;
a first pull-down part including a plurality of transistors connected in series, and configured to pull down the first node to a second off signal in response to any one carry signal among next stages; and
a second pull-down part configured to pull down the N^{th} gate output signal as a first off signal in response to the one carry signal among the next stages,
and wherein the pull-up control part comprises a transistor, and the transistor includes a first gate electrode and a first source electrode connected to a terminal which applies the one carry signal among the previous stages, and a first drain electrode and a second gate electrode connected to the first node.

9. The liquid crystal display device of claim 8, wherein the first and second gate electrodes are first and second control electrodes, and the first source electrode is an input electrode, and the first drain electrode is an output electrode.

10. The liquid crystal display device of claim 9, wherein in the display portion, the first substrate comprises:
a thin film transistor formed on a base substrate;
a first passivation layer disposed on the thin film transistor;
a common electrode disposed on the first passivation layer;
a second passivation layer disposed on the common electrode; and
a pixel electrode disposed on the second passivation layer.

11. The liquid crystal display device of claim 10, wherein the thin film transistor comprises:
a third gate electrode formed on the base substrate;
a gate insulating layer configured to cover the third gate electrode;
a first semiconductor layer disposed on the gate insulating layer; and
a second source electrode and a second drain electrode connected to both end portions of the first semiconductor layer,
wherein the gate insulating layer, the first passivation layer, and the second passivation layer extend toward the peripheral portion.

12. The liquid crystal display device of claim 11, wherein the transistor comprises:
the first gate electrode disposed on the base substrate;
a second semiconductor layer disposed on the gate insulating layer, and including a channel area;
the first source electrode and the first drain electrode connected to both ends of the first semiconductor layer; and
a second gate electrode disposed on the first passivation layer, and configured to overlap a portion of the channel area in a direction from the first drain electrode toward the first source electrode.

13. The liquid crystal display device of claim 12, wherein an overlap ratio between the gate electrode and the channel area is equal to or more than 20% and less than 100% of a length of the channel area.

14. The liquid crystal display device of claim 13, wherein the overlap ratio between the gate electrode and the channel area is equal to or more than 20% and less than 60% of the length of the channel area.

15. The liquid crystal display device of claim 13, wherein the second gate electrode is disposed on the first passivation layer, and contacts the drain electrode through a contact hole exposing the drain electrode.

16. The liquid crystal display device of claim 13, wherein the second gate electrode comprises one of a transparent conductive oxide and a low resistive metal.

17. The liquid crystal display device of claim 16, wherein the low resistive metal comprises one of MoTi, Cu, MoNb, Mo, Cr, and AlNd.

18. The liquid crystal display device of claim 13, wherein the semiconductor layer comprises an oxide semiconductor material.
